(19) United States
(12) Patent Application Publication
(10) Pub. No.: US 2026/0013118 A1
(43) Pub. Date: Jan. 8, 2026

(54) SEMICONDUCTOR DEVICES

(71) Applicant: Samsung Electronics Co., Ltd., Suwon-si (KR)

(72) Inventors: Han-Bo-Ram LEE, Incheon (KR); Yongjin KIM, Suwon-si (KR); Summal ZOHA, Incheon (KR); Sanghoon AHN, Suwon-si (KR); Minkyoung LEE, Suwon-si (KR); Woojin LEE, Suwon-si (KR); Hangyeol CHOI, Suwon-si (KR)

(73) Assignees: Samsung Electronics Co., Ltd., Suwon-si (KR); INCHEON NATIONAL UNIVERSITY RESEARCH & BUSINESS FOUNDATION, Incheon (KR)

(21) Appl. No.: 19/013,337

(22) Filed: Jan. 8, 2025

(30) Foreign Application Priority Data
Jul. 2, 2024 (KR) 10-2024-0087160

(51) Int. Cl. H10B 12/00

(52) U.S. Cl. CPC H10B 12/485; H10B 12/0335; H10B 12/315

(57) ABSTRACT

A semiconductor device may include a semiconductor pattern extending in a first direction, a multi-layered insulating structure on the semiconductor pattern, and a contact penetrating the multi-layered insulating structure. The multi-layered insulating structure may include a first insulating layer and a second insulating layer on the first insulating layer. The contact may include a barrier pattern and a conductive pattern on the barrier pattern. The barrier pattern may contact the first insulating layer and the semiconductor pattern. The conductive pattern may be spaced apart from the semiconductor pattern with the barrier pattern therebetween and the conductive pattern may contact the second insulating layer. The first and second insulating layers may include different materials.

### CROSS-REFERENCE TO RELATED APPLICATIONS

This U.S. non-provisional patent application claims priority under 35 U.S.C. § 119 to Korean Patent Application No. 10-2024-0087160, filed on Jul. 2, 2024, in the Korean Intellectual Property Office, the entire contents of which are hereby incorporated by reference.

### BACKGROUND

Example embodiments are directed a semiconductor device.

Due to their small-size, multifunctionality, and/or low-costs, semiconductor devices are important elements in the electronics industry. The semiconductor devices are classified into a memory device for storing data, a logic device for processing data, and a hybrid device for performing various functions.

As the electronic industry advances, there is an increasing demand for a semiconductor device with a higher integration density. Thus, a process margin in a semiconductor fabrication process to define fine patterns is being reduced, and this leads to challenges in fabricating a semiconductor device. In addition, as the electronic industry advances, a demand for a high-speed/performance semiconductor devices having higher integration density is increasing.

### SUMMARY

Some example embodiments of the inventive concepts are directed to a semiconductor device having a lower electric resistance between a contact and a semiconductor pattern.

According to some example embodiments of the inventive concepts, a semiconductor device may include a semiconductor pattern extending in a first direction, a multi-layered insulating structure on the semiconductor pattern, and a contact penetrating the multi-layered insulating structure. The multi-layered insulating structure may include a first insulating layer and a second insulating layer on the first insulating layer. The contact may include a barrier pattern and a conductive pattern on the barrier pattern. The barrier pattern may contact the first insulating layer and the semiconductor pattern. The conductive pattern may be spaced apart from the semiconductor pattern with the barrier pattern therebetween and the conductive pattern may contact the second insulating layer. The first and second insulating layers may include different insulating materials.

Additionally or alternatively, according to some example embodiments of the inventive concepts, a semiconductor device may include a semiconductor pattern extending in a first direction, a multi-layered insulating structure on the semiconductor pattern, and a contact penetrating the multi-layered insulating structure. The multi-layered insulating structure may include a first insulating layer and a second insulating layer on the first insulating layer. The contact may include a barrier pattern and a conductive pattern on the barrier pattern. The barrier pattern may include a first portion in contact with the semiconductor pattern and the first insulating layer and a second portion in contact with the second insulating layer. The conductive pattern may be spaced apart from the semiconductor pattern, with the barrier pattern interposed therebetween. In the barrier pattern, a width of the second portion in a second direction perpendicular to the first direction may be smaller than a width of the first portion in the second direction, and the first and second insulating layers may include different insulating materials.

According to some example embodiments of the inventive concepts, a semiconductor device may include a bit line extending in a first direction, a semiconductor pattern on the bit line, the semiconductor pattern including a horizontal portion extending in the first direction and a vertical portion extending in a second direction perpendicular to a top surface of the bit line, a word line on the horizontal portion and adjacent to the vertical portion in the first direction, a gate insulating pattern between the vertical portion and the word line, a landing pad on the vertical portion and spaced apart from the bit line with the vertical portion therebetween, a first insulating layer on the bit line and adjacent to the vertical portion in the first direction and spaced apart from the gate insulating pattern with the vertical portion therebetween, a second insulating layer on the first insulating layer, and a barrier pattern between the landing pad and the vertical portion. The barrier pattern may contact the vertical portion, the gate insulating pattern, and the first insulating layer. A level of a bottom surface of the landing pad may be lower than a level of a top surface of the second insulating layer. The first insulating layer and the gate insulating pattern may include one of oxide and nitride materials, and the second insulating layer may include the other of the oxide and nitride materials.

### BRIEF DESCRIPTION OF THE DRAWINGS

FIG. 1 schematically illustrates a semiconductor device, according to some example embodiments of the inventive concepts.

FIGS. 2A, 2B, 2C, and 2D schematically illustrate a method of fabricating a semiconductor device, according to some example embodiments of the inventive concepts.

FIG. 3 is a schematic diagram of a semiconductor device, according to some example embodiments of the inventive concepts.

FIG. 4A is a schematic diagram of a semiconductor device, according to some example embodiments of the inventive concepts.

FIG. 4B is a schematic diagram of a semiconductor device, according to some example embodiments of the inventive concepts.

FIG. 5A is a graph showing the results of experiment 1 executed on samples 1 to 4.

FIG. 5B is a graph showing the results of experiment 2 executed on samples 2, 4, and 5.

FIG. 6 illustrates a semiconductor memory device including a semiconductor device, according to some example embodiments of the inventive concepts.

FIG. 7 is a perspective view schematically illustrating a semiconductor device according to some example embodiments of the inventive concepts.

FIG. 8 is a plan view illustrating a semiconductor device, according to some example embodiments of the inventive concepts.

FIGS. 9, 10, 11, and 12 are sectional views taken along lines A-A′, B-B′, C-C′, and D-D′ of FIG. 8, respectively.

FIG. 13A is an enlarged sectional view illustrating a portion ‘A’ of FIG. 12, according to some example embodiments.

FIG. 13B is an enlarged sectional view illustrating the portion ‘A’ of FIG. 12, according to some example embodiments.

FIG. 14A is an enlarged sectional view illustrating the portion ‘A’ of FIG. 12, according to some example embodiments.

FIG. 14B is an enlarged sectional view illustrating the portion ‘A’ of FIG. 12, according to some example embodiments.

### DETAILED DESCRIPTION

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

Example embodiments of the inventive concepts will now be described with reference to the accompanying drawings.

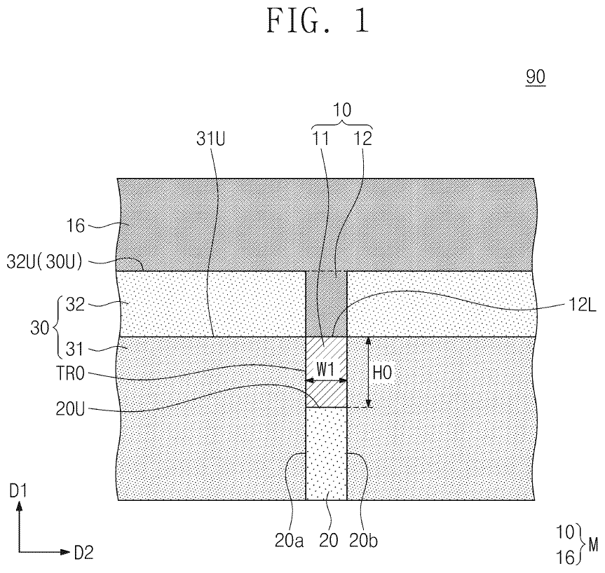

FIG. 1 schematically illustrates a semiconductor device, according to some example embodiments of the inventive concepts.

Referring to FIG. 1, a semiconductor device 90 may include a semiconductor pattern 20, a multi-layered insulating structure 30, and an interconnection pattern M.

The semiconductor pattern 20 may include a first side surface 20a and a second side surface 20b, which are opposite to each other. The semiconductor pattern 20 may extend in a first direction D1. The semiconductor pattern 20 may include silicon (Si), germanium (Ge), silicon-germanium (Si—Ge), an oxide semiconductor material, or the like.

The oxide semiconductor material may include at least one of, for example, indium-gallium-zinc oxide (IGZO) or indium-tin oxide (ITO), but example embodiments are not limited thereto. The oxide semiconductor material may include other material depending on application and/or design. The semiconductor pattern 20 may be a single- or multi-layered structure including the oxide semiconductor material. The semiconductor pattern 20 may include an amorphous, crystalline, and/or polycrystalline oxide semiconductor material.

The multi-layered insulating structure 30 may be provided on the semiconductor pattern 20. The multi-layered insulating structure 30 may be in direct contact with the first and second side surfaces 20a and 20b of the semiconductor pattern 20. A height (e.g., in the first direction D1) of a top surface 30U of the multi-layered insulating structure 30 may be higher than a height of a top surface 20U of the semiconductor pattern 20.

The multi-layered insulating structure 30 may include a first insulating layer 31 and a second insulating layer 32 on the first insulating layer 31. The first insulating layer 31 may be in direct contact with the first and second side surfaces 20a and 20b of the semiconductor pattern 20 in a second direction D2 perpendicular to the first direction D1.

The first and second insulating layers 31 and 32 may include different insulating materials from each other. For example, each of the first and second insulating layers 31 and 32 may be formed of or include one of oxide and nitride materials, and the materials of the first and second insulating layers 31 and 32 may be different from each other.

In some example embodiments, the first insulating layer 31 may be or include at least one of silicon oxide or metal oxide. The metal oxide may be, for example, aluminum oxide. In some example embodiments, the second insulating layer 32 may be or include at least one of silicon nitride or metal nitride. The metal nitride may be, for example, aluminum nitride.

The multi-layered insulating structure 30 may include a trench TR0 exposing the top surface 20U of the semiconductor pattern 20. A width W1 of the trench TR0 in the second direction D2 may range from 0.1 nm (or about 0.1 nm) to 100 nm (or about 100 nm), from 0.5 nm (or about 0.5 nm) to 50 nm (or about 50 nm), or from 1 nm (or about 1 nm) to 20 nm (or about 20 nm).

The interconnection pattern M may include an interconnection line 16 and a contact 10, which are connected to each other.

The contact 10 may extend into the multi-layered insulating structure 30 in the first direction D1 to fill the trench TR0. The contact 10 may penetrate the entirety of a thickness of the second insulating layer 32 and a portion of the first insulating layer 31 in the first direction D1. The contact 10 may include a barrier pattern 11 and a conductive pattern 12 on the barrier pattern 11.

The barrier pattern 11 may be adjacent to the first insulating layer 31 in the second direction D2 and may be in direct contact with the first insulating layer 31. The conductive pattern 12 may be adjacent to the second insulating layer 32 in the second direction D2 and may be in direct contact with the second insulating layer 32. The barrier pattern 11 may be in direct contact with the semiconductor pattern 20 and the conductive pattern 12 in the first direction D1, and the conductive pattern 12 may be spaced apart from the semiconductor pattern 20 in the first direction D1 with the barrier pattern 11 interposed therebetween. A level of a bottom surface 12L of the conductive pattern 12 may be lower than a level of a top surface 32U of the second insulating layer 32. It will be understood that the top surface 30U of the multi-layered insulating structure 30 is the same (or about the same) as the top surface 32U of the second insulating layer 32, and these have been labelled differently for the sake of explanation.

In some example embodiments, in the trench TR0, a height H0 of the barrier pattern 11 in the first direction D1 may range from 0.15 nm (or about 0.15 nm) to 150 nm (or about 150 nm), from 0.75 nm (or about 0.75 nm) to 75 nm (or about 75 nm), or from 1.5 nm (or about 1.5 nm) to 30 nm (or about 30 nm). In some example embodiments, the height H0 of the barrier pattern 11 in the first direction D1 may be greater than the width W1 of the trench TR0 in the second direction D2. In some example embodiments, the height H0 of the barrier pattern 11 in the first direction D1 may be less than twice the width W1 of the trench TR0 in the second direction D2.

In some example embodiments, the barrier pattern 11 may include at least one of metal nitride materials (e.g., titanium nitride (TiN) and tantalum nitride (TaN)). The conductive pattern 12 may include a material having electric conductivity higher than the barrier pattern 11. In some example embodiments, the conductive pattern 12 may include at least one of pure metals, metal alloys, metal nitride materials, metal oxide materials, or doped polysilicon. In some example embodiments, the conductive pattern 12 may include at least one of W, Mo, and Cu.

The interconnection line 16 may be disposed on the contact 10 and the multi-layered insulating structure 30. The interconnection line 16 may extend in the second direction D2. The interconnection line 16 may include a material having electric conductivity greater than the barrier pattern 11. In some example embodiments, the interconnection line 16 may include at least one of pure metals, metal alloys, metal nitride materials, metal oxide materials, or doped polysilicon. In some example embodiments, the interconnection line 16 may include at least one of W, Mo, and Cu. In some example embodiments, the interconnection line 16 may be or include substantially the same material as the conductive pattern 12.

According to some example embodiments of the inventive concepts, the semiconductor pattern 20 may be or include a channel region of a transistor. Opposite ends of the semiconductor pattern 20 may be or include source/drain electrodes of the transistor. The contact 10 may be electrically connected to one of the opposite ends of the semiconductor pattern 20.

In some example embodiments, the barrier pattern 11 may not be interposed (or may be absent) between the second insulating layer 32 and the semiconductor pattern 20. Alternatively, only a relatively smaller barrier pattern 11 may be interposed between the second insulating layer 32 and the semiconductor pattern 20. As a result, it may be possible to reduce the height H0 of the barrier pattern 11 in the first direction D1 and a fraction (or portion) of the barrier pattern 11 in the contact 10. A portion of the conductive pattern 12 in the contact 10 may be relatively more than the barrier pattern 11, and an electric resistance between the contact 10 and the semiconductor pattern 20 may be lowered.

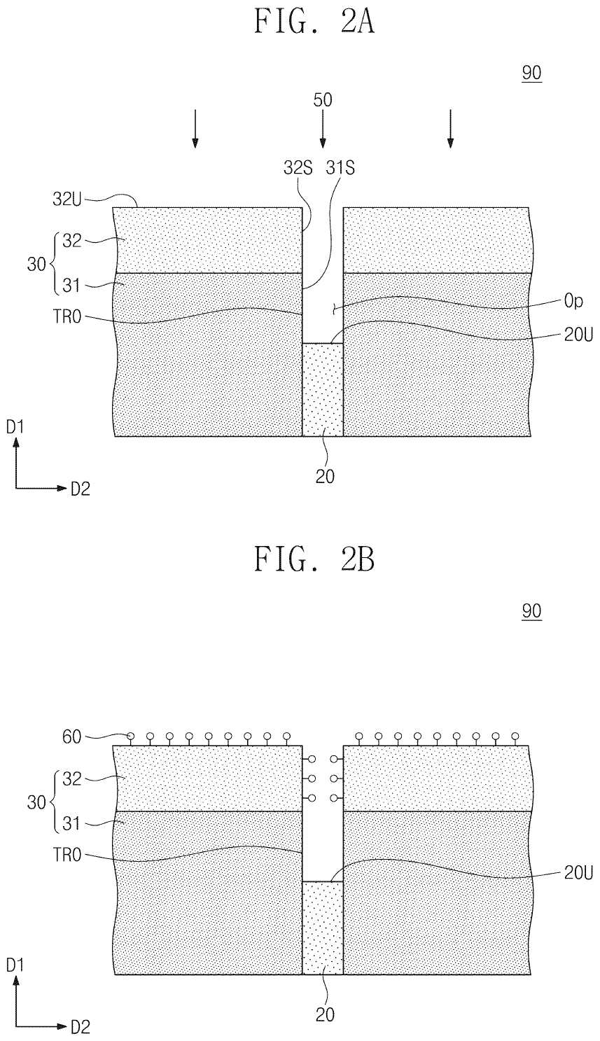

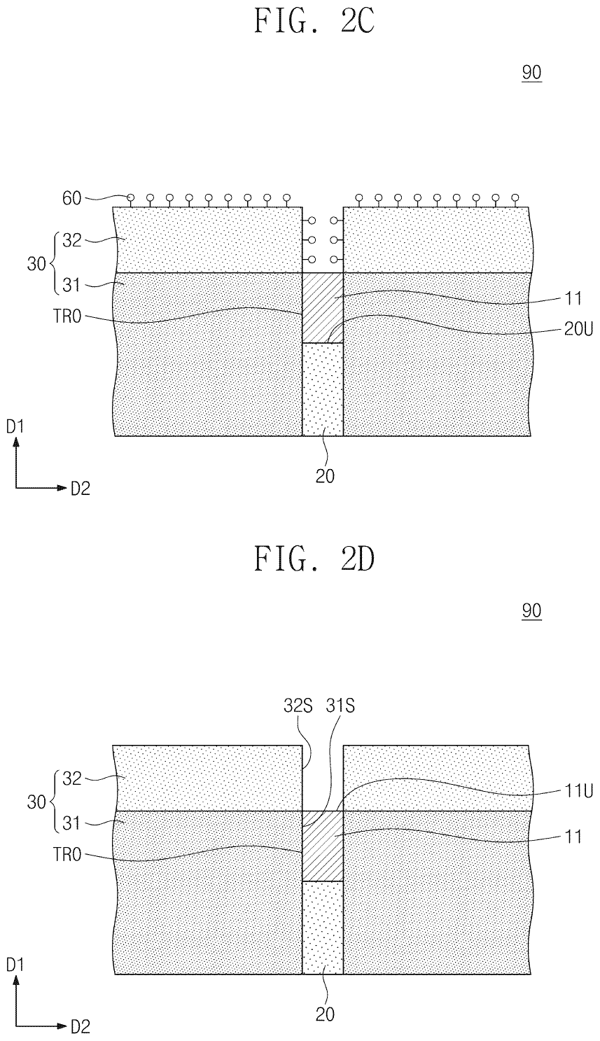

FIGS. 2A to 2D schematically illustrate a method of fabricating a semiconductor device, according to some example embodiments of the inventive concepts.

Referring to FIG. 2A, the semiconductor pattern 20 and the multi-layered insulating structure 30 may be provided. A portion of a side surface 31S of the first insulating layer 31 and a side surface 32S of the second insulating layer 32 may be exposed to the outside through an opening Op formed by the trench TR0. The opening Op may be formed to expose the top surface 20U of the semiconductor pattern 20.

A surface pre-treatment process may be performed to expose the top surface 20U of the semiconductor pattern 20, the side surface 31S of the first insulating layer 31, and the side surface 32S and the top surface 32U of the second insulating layer 32, which are exposed to the outside, to a pre-treatment material 50. In some example embodiments, the surface pre-treatment process may be a wet pre-treatment process or a dry pre-treatment process.

When the wet pre-treatment process is performed, the pre-treatment material 50 may include an acidic aqueous solution. In some example embodiments, the acidic aqueous solution may include at least one of an aqueous HF solution and an aqueous buffered oxide etchant (BOE) solution. The molar concentration of the HF aqueous solution may range from 0.1 M (or about 0.1M) to 2 M (or about 2 M), or from 0.3 M (or about 0.3M) to 1.5 M (or about 1.5M).

When the dry pre-treatment process is performed, the pre-treatment material 50 may contain a gaseous material in a plasma state. In some example embodiments, the gaseous material in the plasma state may include at least one of H₂ or NH₃.

Referring to FIG. 2B, an inhibitor 60 may be deposited on a portion of a surface of the multi-layered insulating structure 30. The inhibitor 60 may be a compound preventing, minimizing or limiting a material from being formed on a specific surface. The inhibitor 60 may be formed on a surface of the second insulating layer 32 exposed to the outside. The inhibitor 60 may not be formed on an unexposed surface of the semiconductor pattern 20 and a surface of the first insulating layer 31. The inhibitor 60 may be formed through one of chemical vapor deposition (CVD), atomic layer deposition (ALD), and molecular layer deposition (MLD) processes, but the formation of the inhibitor 60 may not be limited to a specific method.

In some example embodiments, the inhibitor 60 may include at least one of self-assembled monolayer (SAM) materials and/or small molecule inhibitor (SMI) materials. In some example embodiments, the inhibitor 60 may include one of monomers and polymers.

In some example embodiments, the inhibitor 60 may include a compound having at least one formyl group and may include aldehyde. For example, the inhibitor 60 may include formaldehyde, propionaldehyde, pivaldehyde (or trimethylacetaldehyde), cyclohexanecarboxaldehyde, and trimethylhexanal. As an example, the inhibitor 60 may include 3,5,5-trimethylhexanal. In some example embodiments, the inhibitor 60 may include at least one compound selected from the group consisting of polyimide-based, polyamide-based, polyethylene-based, polypropylene-based, polystyrene-based, or polycarbonate-based compounds.

Referring to FIG. 2C, the barrier pattern 11 may be formed. The barrier pattern 11 may cover the top surface 20U of the semiconductor pattern 20 and the side surface 31S of the first insulating layer 31.

In some example embodiments, the formation of the barrier pattern 11 may include depositing a metal nitride material. In some example embodiments, the barrier pattern 11 may be formed through one of physical vapor deposition (PVD), chemical vapor deposition (CVD), atomic layer deposition (ALD), and/or molecular layer deposition (MLD) processes. Since the surface of the second insulating layer 32 is covered with the inhibitor 60, the barrier pattern 11 may not be deposited on the surface of the second insulating layer 32.

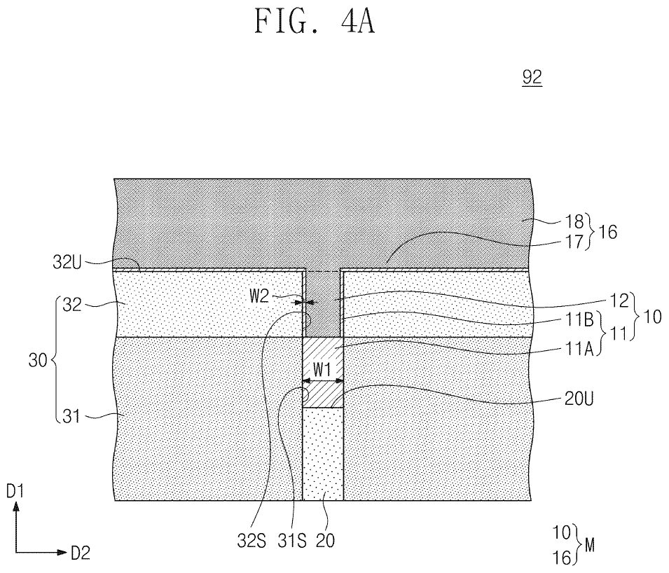

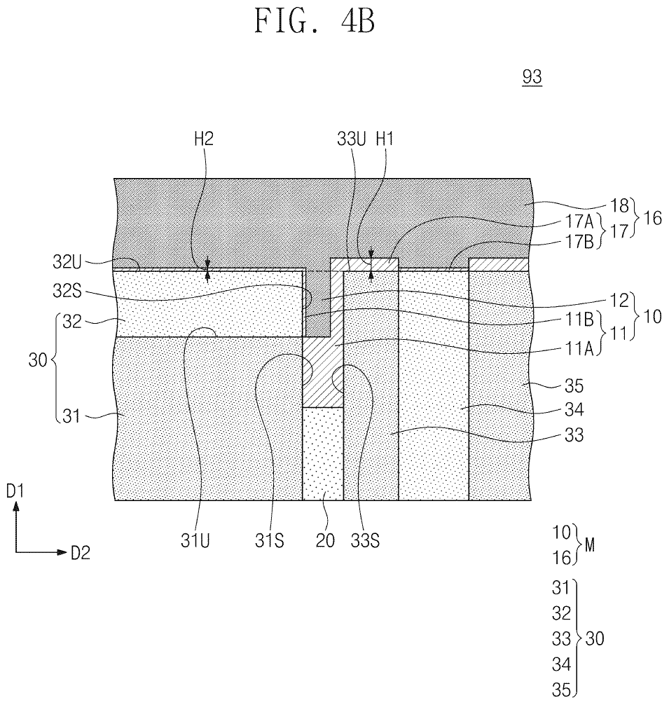

In some example embodiments, a deposition amount of the barrier pattern 11 may be less on the surface of the second insulating layer 32 than on the surface of the first insulating layer 31. A weight of the barrier pattern 11, which is deposited on a given surface area of the multi-layered insulating structure 30, may be compared based on a horizontal width, and this will be described in more detail with reference to FIG. 4A.

Referring to FIG. 2D, the inhibitor 60 may be removed. In some example embodiments, the removal of the inhibitor 60 may include exposing a top surface 11U of the barrier pattern 11, the side surface 31S of the first insulating layer 31, and the side surface 32S and the top surface 32U of the second insulating layer 32 to a post-treatment material. The inhibitor 60 may be removed through a wet process and/or a dry process.

When the wet process is performed, the post-treatment material may include an acidic aqueous solution. In some example embodiments, the acidic aqueous solution may be an aqueous solution of H₃PO₄. When the dry process is performed, the post-treatment material may include a gaseous material in a plasma state. In some example embodiments, the gaseous material in the plasma state may include at least one of H₂ or NH₃.

Since the inhibitor 60 is removed, the surface of the second insulating layer 32 may be exposed. Referring back to FIG. 1, the conductive pattern 12 may be deposited on the surface of the second insulating layer 32 and the surface of the barrier pattern 11, which are exposed to the outside. In some example embodiments, a relatively thin layer of the barrier pattern 11 may be formed on the surface of the second insulating layer 32 and, instead of the surface of the second insulating layer 32, the surface of the thin layer of the barrier pattern 11 may be exposed, as will be described with reference to FIG. 4A. As a result, the conductive pattern 12 may be deposited on the exposed surface of the barrier pattern 11.

In some example embodiments, the conductive pattern 12 may be formed through one of physical vapor deposition (PVD), chemical vapor deposition (CVD), atomic layer deposition (ALD), and molecular layer deposition (MLD) processes.

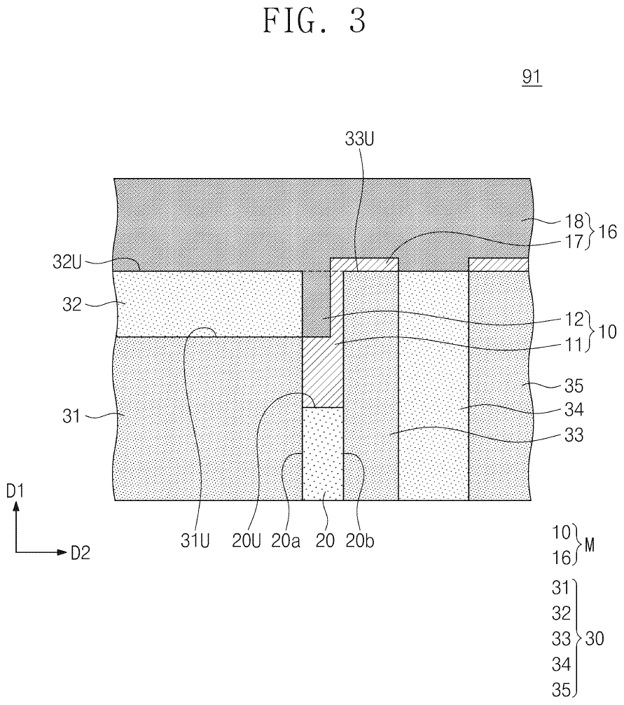

FIG. 3 is a schematic diagram of a semiconductor device 91, according to some example embodiments of the inventive concepts. The semiconductor device 91 may be similar in some respects to the semiconductor device 90 of FIG. 1, and therefore may be best understood with reference thereto where like numerals indicate like elements not described again in detail.

Referring to FIG. 3, the multi-layered insulating structure 30 may further include a third insulating layer 33, a fourth insulating layer 34, and a fifth insulating layer 35. The third, fourth, and fifth insulating layers 33, 34, and 35 may be disposed on the second side surface 20b of the semiconductor pattern 20. The third insulating layer 33 may be in contact (e.g., direct contact) with the second side surface 20b of the semiconductor pattern 20.

The third, fourth, and fifth insulating layers 33, 34, and 35 may be arranged side by side in the second direction D2. The fourth insulating layer 34 may be interposed between the third insulating layer 33 and the fifth insulating layer 35. The fourth and fifth insulating layers 34 and 35 may be spaced apart from the first and second insulating layers 31 and 32 in the second direction D2.

The third, fourth, and fifth insulating layers 33, 34, and 35 may be in contact with the interconnection line 16 in the first direction D1. The interconnection line 16 may include a barrier interconnection line 17 and a conductive interconnection line 18 on the barrier interconnection line 17. The conductive interconnection line 18 may correspond to the interconnection line 16 of FIG. 1. The barrier interconnection line 17 may be interposed between the third insulating layer 33 and the conductive interconnection line 18 and between the fifth insulating layer 35 and the conductive interconnection line 18. The barrier interconnection line 17 may be absent between the fourth insulating layer 34 and the conductive interconnection line 18.

The third insulating layer 33 may be in contact with the barrier pattern 11 in the second direction D2. The barrier pattern 11 may be interposed between the conductive pattern 12 and the third insulating layer 33 in the second direction D2.

A top surface 33U of the third insulating layer 33 may be higher than the top surface 20U of the semiconductor pattern 20. The top surface 33U of the third insulating layer 33 may be higher than or at a same level as a top surface 31U of the first insulating layer 31.

In some example embodiments, the third insulating layer 33 and/or the fifth insulating layer 35 may include at least one of, for example, silicon oxide or metal oxide materials. The metal oxide materials may include, for example, aluminum oxide.

In some example embodiments, the fourth insulating layer 34 may include at least one of, for example, silicon nitride or metal nitride materials. The metal nitride materials may include, for example, aluminum nitride.

FIG. 4A is a schematic diagram of a semiconductor device 92, according to some example embodiments of the inventive concepts. The semiconductor device 92 may be similar in some respects to the semiconductor device 90 of FIG. 1, and therefore may be best understood with reference thereto where like numerals indicate like elements not described again in detail.

The barrier pattern 11 of the contact 10 may include a first portion 11A and a second portion 11B on the first portion 11A. The first portion 11A may correspond to the barrier pattern 11 of FIG. 1. The second portion 11B may be disposed on the side surface 32S of the second insulating layer 32 and may be in direct contact with the second insulating layer 32.

A width W2 of the second portion 11B in the second direction D2 may be smaller than a width W1 of the first portion 11A in the second direction D2. In some example embodiments, the width W2 of the second portion 11B in the second direction D2 may be between 0.0001% and 10%, between 0.001% and 5%, between 0.01% and 3%, between 0.5% and 2%, or between 0.1% and 1% of the width W1 of the first portion 11A in the second direction D2.

In some example embodiments, the interconnection line 16 may include the barrier interconnection line 17 and the conductive interconnection line 18 on the barrier interconnection line 17. The conductive interconnection line 18 may correspond to the interconnection line 16 of FIG. 1. The barrier interconnection line 17 may be interposed between the top surface 32U of the second insulating layer 32 and the conductive interconnection line 18.

FIG. 4B is a schematic diagram of a semiconductor device 93, according to some example embodiments of the inventive concepts. The semiconductor device 93 may be similar in some respects to the semiconductor devices 90, 91, and 92 of FIGS. 1, 3, and 4A, respectively, and therefore may be best understood with reference thereto where like numerals indicate like elements not described again in detail.

The barrier pattern 11 of the contact 10 may include the first portion 11A and the second portion 11B on the first portion 11A. The first portion 11A may be disposed on the side surface 31S of the first insulating layer 31 and may extend to a side surface 33S of the third insulating layer 33. In some example embodiments, and as illustrated, the first portion 11A may be formed on the entire side surface 33S of the third insulating layer 33 not occupied by the semiconductor pattern 20. The first portion 11A may be in direct contact with the first insulating layer 31 and the third insulating layer 33. The first portion 11A may correspond to the barrier pattern 11 of FIG. 1. The second portion 11B may be disposed on the side surface 32S of the second insulating layer 32 and may be in direct contact with the second insulating layer 32.

The interconnection line 16 may include the barrier interconnection line 17 and the conductive interconnection line 18 on the barrier interconnection line 17. The conductive interconnection line 18 may correspond to the interconnection line 16 of FIG. 3.

The barrier interconnection line 17 may be interposed between the top surface 32U of the second insulating layer 32 and the conductive interconnection line 18. The barrier interconnection line 17 may include a first portion 17A and a second portion 17B. The first portion 17A may be interposed between the third insulating layer 33 and the conductive interconnection line 18 and between the fifth insulating layer 35 and the conductive interconnection line 18. The second portion 17B may be interposed between the second insulating layer 32 and the conductive interconnection line 18 and between the fourth insulating layer 34 and the conductive interconnection line 18.

A height H2 of the second portion 17B of the barrier interconnection line 17 in the first direction D1 may be smaller than a height H1 of the first portion 17A in the first direction D1. In some example embodiments, the height H2 of the second portion 17B in the first direction D1 may range between 0.0001% and 10%, between 0.001% and 5%, between 0.01% and 3%, between 0.5% and 2%, or between 0.1% and 1% of the height H1 of the first portion 17A in the first direction D1.

### [Sample 1]

Sample 1 was prepared to include a silicon nitride (Si₃N₄) layer exposed to 3,5,5-trimethylhexanal (hereinafter, TMH) serving as an inhibitor.

### [Sample 2]

Sample 1 was prepared to include a silicon oxide (SiO₂) layer exposed to the TMH.

### [Sample 3]

A surface pre-treatment step was performed before the TMH exposure step, and except for this, Sample 3 was prepared using the same process as Sample 1. In the surface pre-treatment step, the silicon nitride layer was exposed to 0.6M HF aqueous solution for 30 seconds.

### [Sample 4]

Sample 4 was prepared using the same process as Sample 3, except that the silicon nitride was exposed to the HF aqueous solution for 60 seconds.

### [Sample 5]

Sample 5 was prepared using the same process as Sample 4, except that 1.2M HF aqueous solution was used.

### [Experiment 1]

The water contact angle (WCA) was measured from the samples while varying the exposure time(s) to the TMH.

### [Experiment 2]

A hafnium oxide (HfO₂) layer was deposited on the samples, after the experiment 1. After the deposition, an X-ray Diffraction (XRD) analysis was executed.

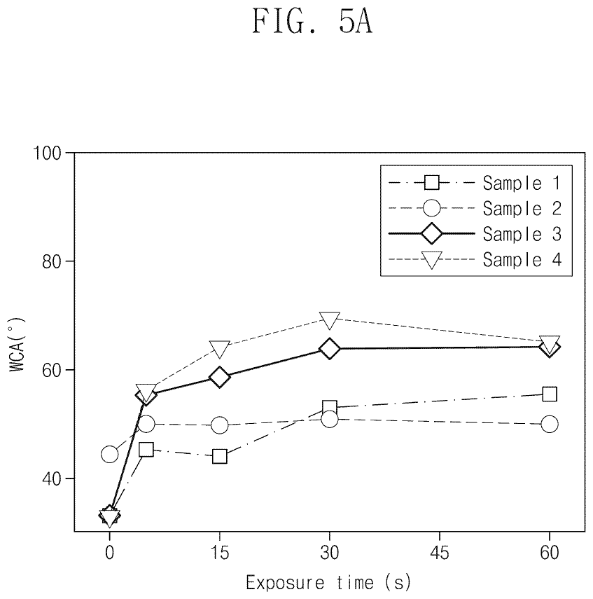

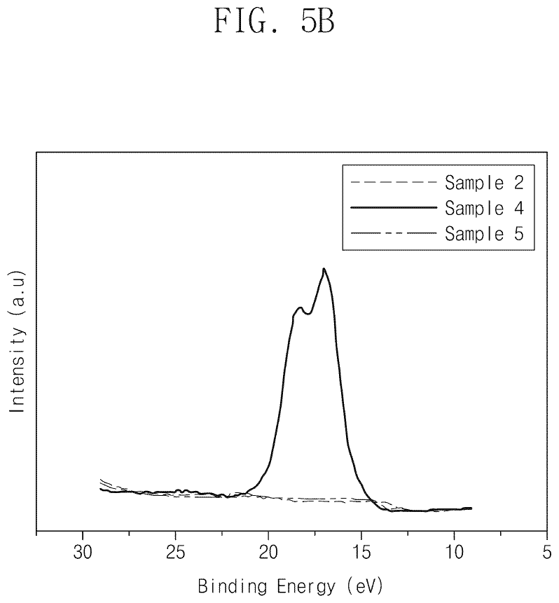

FIG. 5A shows the results of the experiment 1 executed on the samples 1 to 4.

FIG. 5A shows how effectively the inhibitor is deposited when the silicon oxide layer and the silicon nitride layer were exposed to the inhibitor. Since a higher water contact angle (WCA) indicates more effective deposition of the TMH, FIG. 5A shows that the TMH was not deposited on the sample 2, compared to the samples 1, 3, and 4.

FIG. 5B shows the results of the experiment 2 executed on the samples 2, 4, and 5.

Referring to FIG. 5B, a peak associated with the 4f orbital of hafnium oxide was found in the sample 2 but not in the samples 4 and 5. This shows that the hafnium oxide layer is poorly deposited on the samples 4 and 5.

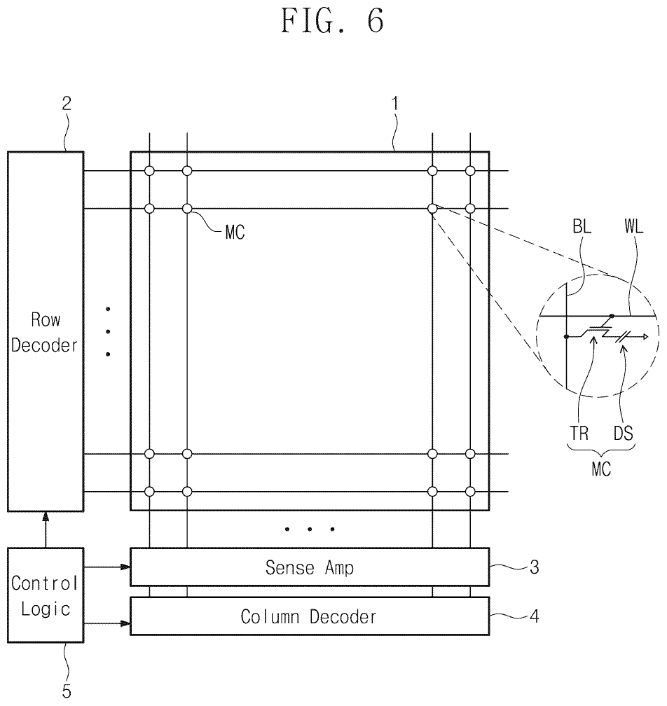

FIG. 6 illustrates a semiconductor memory device including a semiconductor device, according to some example embodiments of the inventive concepts.

Referring to FIG. 6, the semiconductor memory device may include a memory cell array 1, a row decoder 2, a sense amplifier 3, a column decoder 4, and a control logic 5. The memory cell array 1 may include a plurality of memory cells MC, which

are two- or three-dimensionally arranged. Each of the memory cells MC may be provided between and connected to a word line WL and a bit line BL, which cross each other.

Each of the memory cells MC may include a selection element TR and a data storage element DS, which are electrically connected to each other in series. The selection element TR may be provided between and connected to the data storage element DS and the word line WL, and the data storage element DS may be connected to the bit line BL through the selection element TR. The selection element TR may be a field effect transistor (FET), and the data storage element DS may be realized by a capacitor, a magnetic tunnel junction pattern, or a variable resistor. In some example embodiments, the selection element TR may include a transistor having a gate electrode, which is connected to the word line WL, and drain/source terminals, which are connected to the bit line BL and the data storage element DS, respectively.

The row decoder 2 may be configured to decode address information, which is input from the outside, and to select one of the word lines WL of the memory cell array 1, based on the decoded address information. The address information decoded by the row decoder 2 may be provided to a row driver, and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which may be selected based on address information decoded by the column decoder 4, and a reference bit line.

The column decoder 4 may provide a data transmission path between the sense amplifier 3 and an external device (e.g., a memory controller). The column decoder 4 may be configured to decode address information, which may be input from the outside, and to select one of the bit lines BL, based on the decoded address information.

The control logic 5 may generate control signals, which may be used to control writing or reading operations on the memory cell array 1.

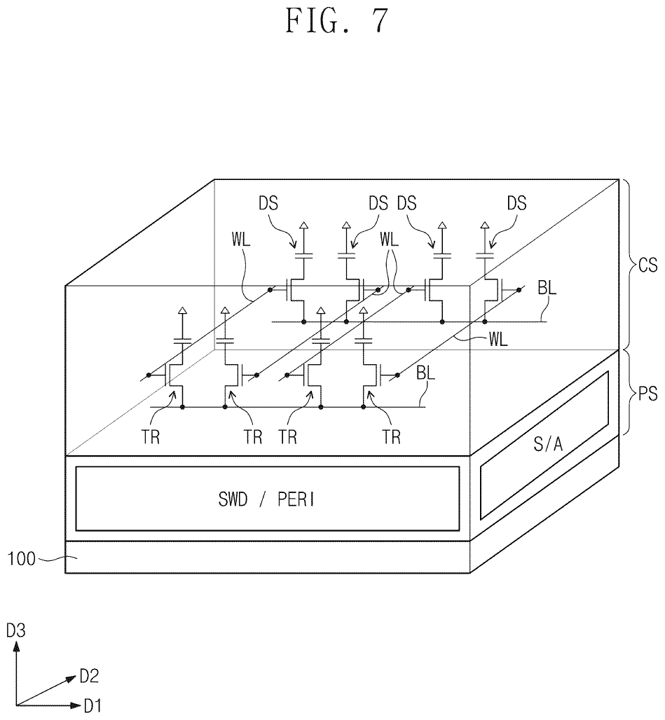

FIG. 7 is a perspective view schematically illustrating a semiconductor device, according to some example embodiments of the inventive concepts.

Referring to FIG. 7, the semiconductor device may include a peripheral circuit structure PS on a substrate 100 and a cell array structure CS on the peripheral circuit structure PS.

The peripheral circuit structure PS may include core and peripheral circuits formed on the substrate 100. The core and peripheral circuits may include the row and column decoders 2 and 4, the sense amplifier 3, and the control logic 5 described with reference to FIG. 6. The peripheral circuit structure PS may be provided between the substrate 100 and the cell array structure CS, in a third direction D3 perpendicular to a top surface of the substrate 100.

The cell array structure CS may include the bit lines BL, the word lines WL, and the memory cells MC (e.g., of FIG. 6) therebetween. The memory cells MC (e.g., see FIG. 6) may be two- or three-dimensionally arranged on a plane that is parallel to the top surface of the substrate 100 and is extended in two different directions (e.g., first and second directions D1 and D2). Each of the memory cells MC of FIG. 6 may include the selection element TR and the data storage element DS, as described above.

In some example embodiments, each memory cell (MC of FIG. 6) may include a vertical channel transistor (VCT), which is used as the selection element TR. The vertical channel transistor may be configured to include a channel region that is extended in a direction (i.e., the third direction D3) perpendicular to the top surface of the substrate 100. In addition, each of the memory cells MC (e.g., of FIG. 6) may include a capacitor, which is used as the data storage element DS.

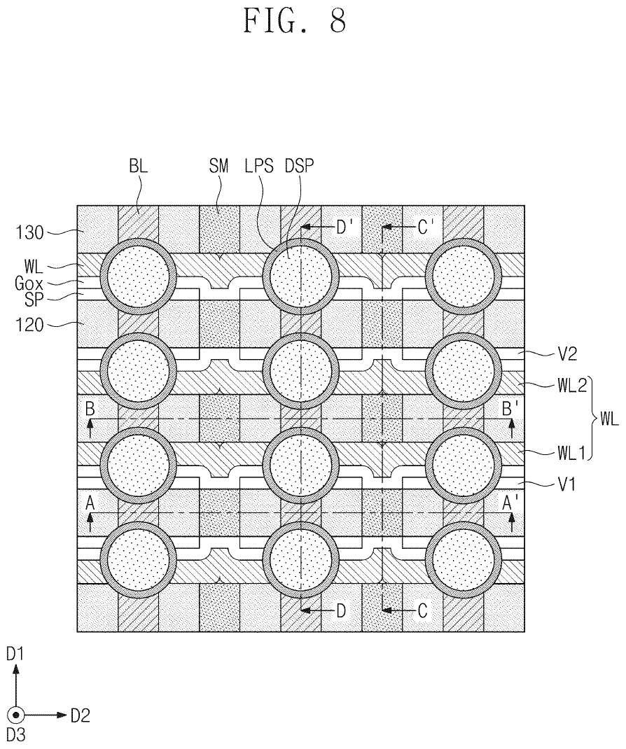

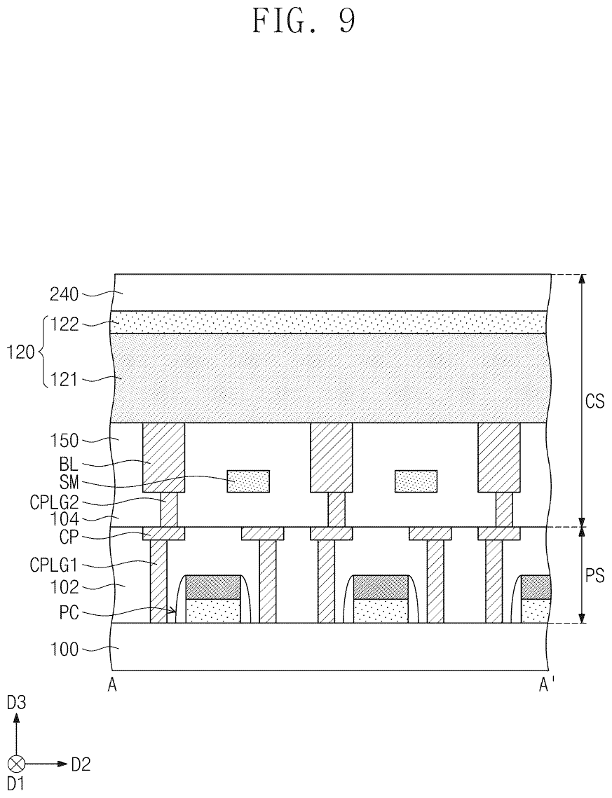

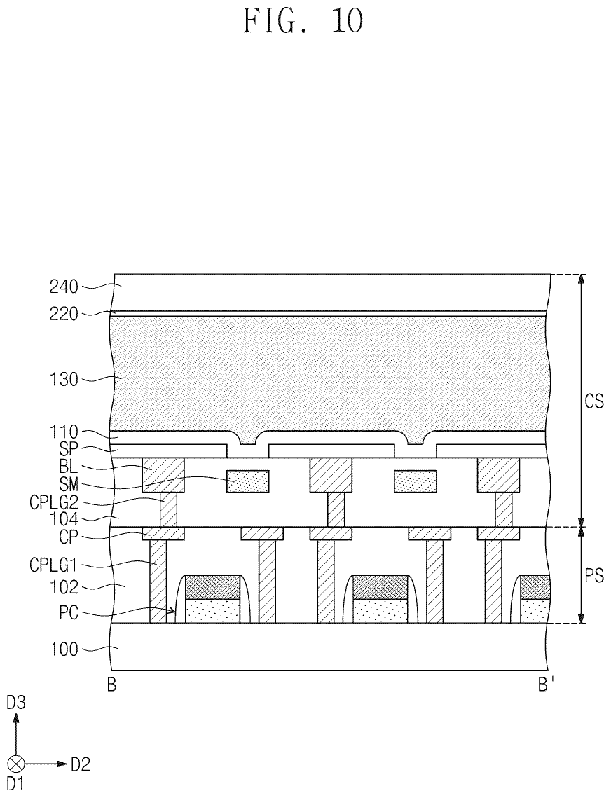

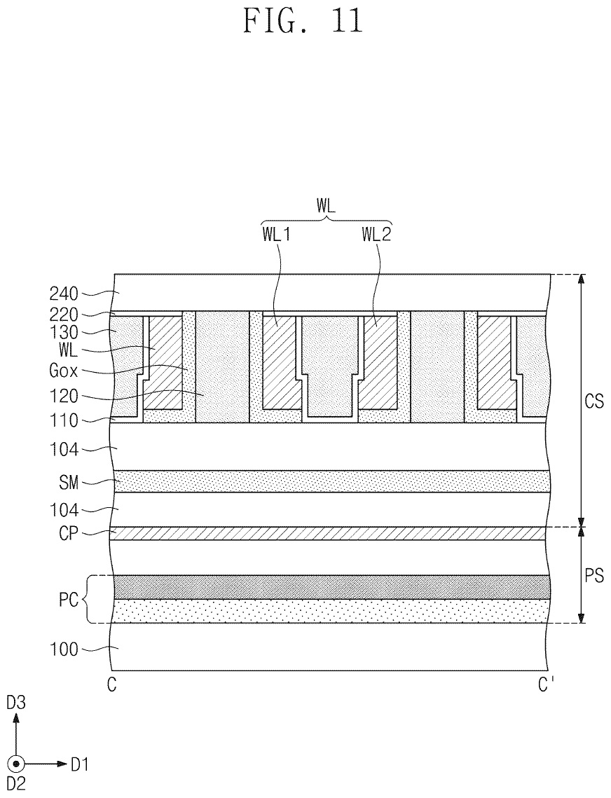

FIG. 8 is a plan view illustrating a semiconductor device, according to some example embodiments of the inventive concepts. FIGS. 9 to 12 are sectional views taken along lines A-A′, B-B′, C-C′, and D-D′ of FIG. 8, respectively.

Referring to FIGS. 8 to 12, the semiconductor device may include the substrate 100, the peripheral circuit structure PS on the substrate 100, and the cell array structure CS on the peripheral circuit structure PS.

The substrate 100 may be a semiconductor substrate. In some example embodiments, the substrate 100 may be, for example, a silicon substrate, a germanium substrate, or a silicon-germanium substrate.

The peripheral circuit structure PS may include a peripheral gate structure PC, peripheral contact pads CP, peripheral contact plugs CPLG1, and a first interlayer insulating layer 102, which are provided on the substrate 100, and the first interlayer insulating layer 102 may cover the peripheral gate structure PC, the peripheral contact pads CP, the peripheral contact plugs CPLG1, and the substrate 100. The peripheral gate structure PC may include the sense amplifier 3 of FIG. 6.

The cell array structure CS may include memory cells including vertical channel transistors. The cell array structure CS may include a plurality of cell contact plugs CPLG2, a plurality of bit lines BL, a plurality of shielding structures SM, a second interlayer insulating layer 104, a plurality of semiconductor patterns SP, a plurality of word lines WL, a plurality of gate insulating patterns Gox, and data storage patterns DSP. The second interlayer insulating layer 104 may cover the cell contact plugs CPLG2 and the shielding structures SM.

In some example embodiments, the peripheral gate structures PC of the peripheral circuit structure PS may be electrically connected to the bit lines BL through the peripheral contact plugs CPLG1, the peripheral contact pads CP, and the cell contact plugs CPLG2. In some example embodiments, each of the first and second interlayer insulating layers 102 and 104 may include a plurality of insulating layers stacked in a multi-layered structure and may be formed of or include at least one of silicon oxide, silicon nitride, silicon oxynitride, or low-k dielectric materials.

The bit line BL may be provided on the substrate 100 and may extend in the first direction D1. In some example embodiments, a plurality of bit lines BL may be provided, and the bit lines BL may be spaced apart from each other in the second direction D2. The bit line BL may be electrically connected to the peripheral contact pad CP through the cell contact plug CPLG2.

In some example embodiments, the bit line BL may be formed of or include at least one of doped polysilicon, metallic materials (e.g., Al, Cu, Ti, Ta, Ru, W, Mo, Pt, Ni, and Co), conductive metal nitride materials (e.g., TiN, TaN, WN, NbN, TiAlN, TiSiN, TaSiN, and RuTiN), conductive metal silicide materials, or conductive metal oxide materials (e.g., PtO, RuO₂, IrO₂, SrRuO₃ (SRO), (Ba,Sr)RuO₃ (BSRO), CaRuO₃ (CRO), and LSCo), but example embodiments are not limited thereto. The bit line BL may be a single- or multi-layered structure formed of the afore-described materials. In some example embodiments, the bit line BL may be formed of or include at least one of two-dimensional semiconductor materials (e.g., graphene, carbon nanotube, or combinations thereof).

The shielding structures SM may be provided between the bit lines BL, respectively, and the shielding structures SM may extend along the first direction D1. The shielding structures SM may be formed of or include at least one of conductive materials (e.g., metallic materials). The shielding structures SM may be provided in the second interlayer insulating layer 104, and top surfaces of the shielding structures SM may be placed at a height lower than top surfaces of the bit lines BL.

As an example, the shielding structures SM may be formed of or include a conductive material, and an air gap or void may be formed in the shielding structure SM. As another example, the air gaps may be provided in the second interlayer insulating layer 104 instead of the shielding structures SM.

The semiconductor pattern SP may be disposed on the bit line BL. In some example embodiments, a plurality of semiconductor patterns SP may be provided. The semiconductor patterns SP may be spaced apart from each other in the first and second directions D1 and D2.

The semiconductor pattern SP may include a first vertical portion V1 and a second vertical portion V2, which are opposite to each other, and a horizontal portion H connecting the first and second vertical portions V1 and V2. The horizontal portion H may be placed at a lower level of the first and second vertical portions V1 and V2 to connect the first and second vertical portions V1 and V2 to each other.

Lower portions of the first and second vertical portions V1 and V2 may be in direct contact with an upper portion of the bit line BL.

The horizontal portion H of the semiconductor pattern SP may include a common source/drain region, and upper portions of the first and second vertical portions V1 and V2 may include first and second source/drain regions. The first vertical portion V1 may include a first channel region between the common source/drain region and the first source/drain region, and the second vertical portion V2 may include a second channel region between the common source/drain region and the second source/drain region. Each of the first and second vertical portions V1 and V2 may be electrically connected to the bit line BL. As a result, the semiconductor device may have a structure in which a pair of vertical channel transistors share one bit line BL.

In some example embodiments, the semiconductor pattern SP may include silicon (Si) and/or an oxide semiconductor material. The oxide semiconductor material may include at least one of InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, and InxGayO, but example embodiments are not limited thereto. In some example embodiments, the semiconductor pattern SP may include indium gallium zinc oxide (IGZO) and/or indium tin oxide (ITO). The semiconductor pattern SP may have a single- or multi-layered structure that is made of the oxide semiconductor material. The semiconductor pattern SP may include an amorphous, crystalline, or polycrystalline oxide semiconductor material. In some example embodiments, the semiconductor pattern SP may include a two-dimensional semiconductor material (e.g., graphene, carbon nanotube, or combinations thereof).

The word line WL may be disposed between the first vertical portion V1 and the second vertical portion V2. In some example embodiments, a plurality of word lines WL may be provided. The word lines WL may extend in the second direction D2 and may be spaced apart from each other in the first direction D1.

Each of the word lines WL may include a first word line WL1 and a second word line WL2, and the first word line WL1 and the second word line WL2 may be opposite to each other in the first direction D1. The first word line WL1 may cover an inner side surface of the first vertical portion V1 facing the second vertical portion V2.

The first word line WL1 may be placed near the first channel region of the first vertical portion V1 and may be used to control the first channel region. The second word line WL2 may cover an inner side surface of the second vertical portion V2 facing the first vertical portion V1. The second word line WL2 may be placed near the second channel region of the second vertical portion V2 and may be used to control the second channel region.

In some example embodiments, lower portions of the first and second word lines WL1 and WL2 may protrude toward each other. A width of the lower portions of the first and second word lines WL1 and WL2 in the first direction D1 may be greater than a width of upper portions of the first and second word lines WL1 and WL2. However, example embodiments are not limited thereto, and in some example embodiments, the upper/lower portions of the first and second word lines WL1 and WL2 may have substantially the same width.

In some example embodiments, the word line WL may be formed of or include at least one of doped polysilicon, metallic materials (e.g., Al, Cu, Ti, Ta, Ru, W, Mo, Pt, Ni, and Co), conductive metal nitride materials (e.g., TiN, TaN, WN, NbN, TiAlN, TiSiN, TaSiN, and RuTiN), conductive metal silicide materials, or conductive metal oxide materials (e.g., PtO, RuO₂, IrO₂, SrRuO₃ (SRO), (Ba,Sr)RuO₃ (BSRO), CaRuO₃ (CRO), and LSCo), but the inventive concept is not limited to these examples. The word line WL may be a single- or multi-layered structure formed of the afore-described materials. In some example embodiments, the word line WL may be formed of or include at least one of two-dimensional semiconductor materials (e.g., graphene and carbon nanotube) or combinations thereof.

The gate insulating pattern Gox may be interposed between the semiconductor pattern SP and the word line WL. The gate insulating pattern Gox may be interposed between the inner side surface of the first vertical portion V1 and the first word line WL1 and between the inner side surface of the second vertical portion V2 and the second word line WL2. The gate insulating pattern Gox may extend into a region between the horizontal portion H and the word line WL2. The word line WL may be spaced apart from the semiconductor pattern SP by the gate insulating pattern Gox. The gate insulating pattern Gox may cover the semiconductor pattern SP to a uniform thickness.

In some example embodiments, the gate insulating patterns Gox may be respectively interposed between the first vertical portion V1 and the first word line WL1 and between the second vertical portion V2 and the second word line WL2 and may not be separated from each other on the horizontal portion H. The gate insulating patterns Gox may be spaced apart from each other on the horizontal portion H. In some example embodiments, the gate insulating pattern Gox may be interposed between the first vertical portion V1 and the first word line WL1 and between the second vertical portion V2 and the second word line WL2, may extend to a region on the horizontal portion H, and may be connected to each other.

In some example embodiments, the gate insulating pattern Gox may be formed of or include at least one of silicon oxide, silicon oxynitride, or high-k dielectric materials whose dielectric constants are higher than that of silicon oxide. The high-k dielectric materials may include metal oxide materials. For example, the high-k dielectric materials for the gate insulating pattern Gox may include at least one of HfO₂, HfSiO, HfTaO, HfTiO, HfZrO, ZrO₂, and Al₂O₃, but example embodiments are not limited thereto.

A first insulating pattern 120 may be interposed between the semiconductor patterns SP, which are adjacent to each other in the first direction D1. In some example embodiments, a plurality of first insulating patterns 120 may be provided. The first insulating pattern 120 may include a first lower insulating pattern 121 and a first upper insulating pattern 122 on the first lower insulating pattern 121.

The first insulating patterns 120 may extend in the second direction D2 to cross the bit line BL and may be spaced apart from each other in the first direction D1. The first insulating pattern 120 may cover at least a portion of outer side surfaces of the first and second vertical portions V1 and V2.

In some example embodiments, the first lower insulating pattern 121 may include at least one of silicon oxide or aluminum oxide. The first upper insulating pattern 122 may include silicon nitride. The first insulating pattern 120 may further include an additional insulating pattern.

In some example embodiments, the first insulating pattern 120 may be in contact with a top surface of the bit line BL. The first insulating pattern 120 may cover portions of the outer side surfaces of the first and second vertical portions V1 and V2, which are not buried by the bit line BL.

A second insulating pattern 130 may be disposed between the first word line WL1 and the second word line WL2. In some example embodiments, a plurality of second insulating patterns 130 may be provided. The second insulating patterns 130 may extend in the second direction D2 to cross the bit line BL and may be spaced apart from each other in the first direction D1. The first and second insulating patterns 120 and 130 may be alternately arranged in the first direction D1. The second insulating pattern 130 may be formed of or include at least one of, for example, silicon oxide, silicon nitride, silicon oxynitride, and low-k dielectric materials, but example embodiments are not limited thereto.

A protection pattern 110 may be interposed between the word line WL and the second insulating pattern 130. The protection pattern 110 may cover an inner side surface of the word line WL. In some example embodiments, the protection pattern 110 may be formed of or include at least one of silicon oxide, silicon nitride, and silicon oxynitride, but the inventive concept is not limited to this example.

A capping pattern 220 may be provided on a top surface of the word line WL. The capping pattern 220 may cover the top surfaces of the protection pattern 110 and the second insulating pattern 130. The capping pattern 220 may extend in the second direction D2. In some example embodiments, the capping pattern 220 may include at least one of silicon oxide, silicon nitride, or silicon oxynitride, but example embodiments are not limited thereto.

Landing pad structures LPS may be provided on the first and second vertical portions V1 and V2 of the semiconductor pattern SP, respectively. The landing pad structures LPS may be in direct contact with the first and second vertical portions V1 and V2 and may be electrically connected to the first and second vertical portions V1 and V2. When viewed in a plan view, the landing pad structures LPS may be spaced apart from each other in the first and second directions D1 and D2 and may be arranged in various shapes (e.g., matrix, zigzag, and honeycomb shapes). When viewed in a plan view, each of the landing pad structures LPS may have various shapes (e.g., circular, elliptical, rectangular, square, diamond, and hexagonal shapes).

A third interlayer insulating layer 240 may be provided on the first and second insulating patterns 120 and 130 to fill a space between the landing pad structures LPS. In some example embodiments, the third interlayer insulating layer 240 may be formed of or include at least one of silicon oxide, silicon nitride, or silicon oxynitride and may have a single- or multi-layered structure, but example embodiments are not limited thereto.

The data storage patterns DSP may be provided on the landing pad structures LPS, respectively. The data storage patterns DSP may be electrically connected to the first and second vertical portions V1 and V2 of the semiconductor pattern SP, respectively, through the landing pad structures LPS.

In some example embodiments, each of the data storage patterns DSP may be a capacitor including a bottom electrode, a top electrode, and a capacitor dielectric layer interposed therebetween. The bottom electrode may be in contact with the landing pad structure LPS and may have various shapes (e.g., circular, elliptical, rectangular, square, lozenge, and hexagonal shapes), when viewed in a plan view.

Alternatively, the data storage patterns DSP may be a variable resistance pattern, a resistance of which may be switched to one of at least two states by an electric pulse applied thereto. In some example embodiments, the data storage patterns DSP may be formed of or include at least one of phase-change materials whose crystal state can be changed depending on an amount of a current applied thereto, perovskite compounds, transition metal oxides, magnetic materials, ferromagnetic materials, or antiferromagnetic materials.

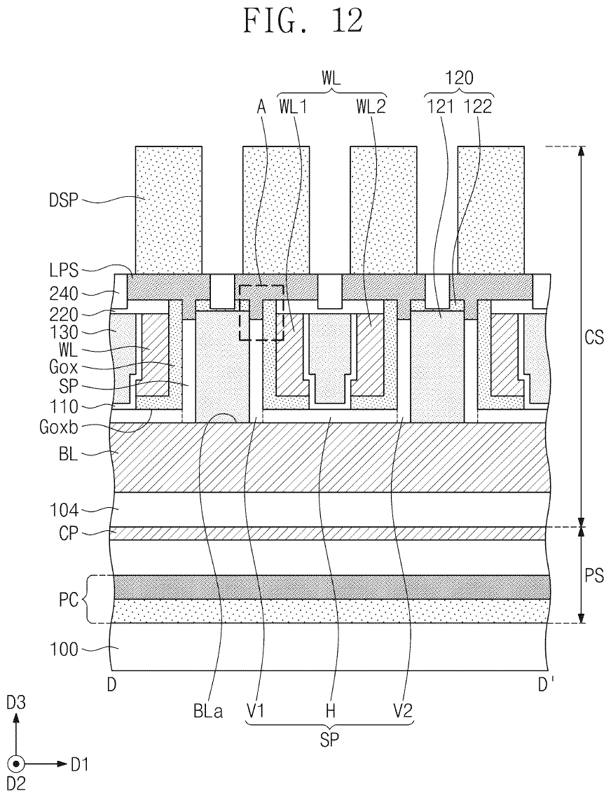

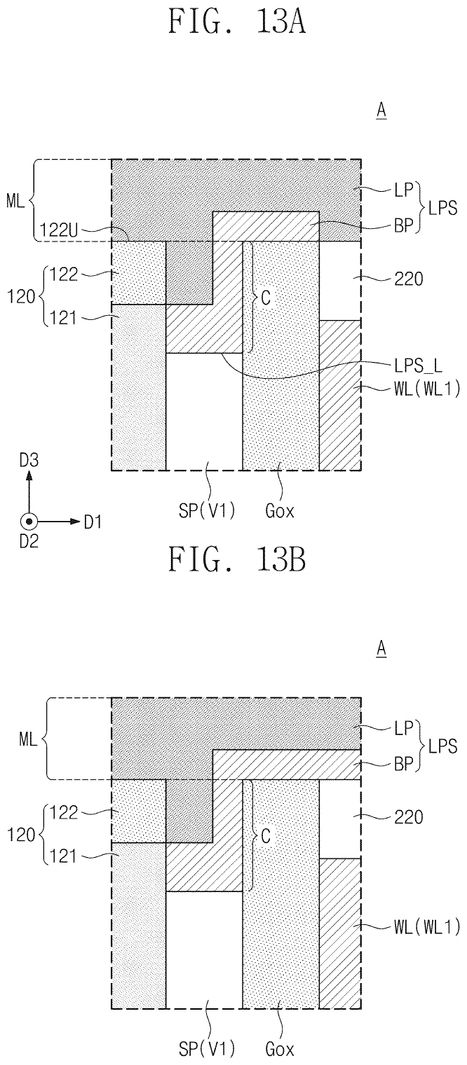

FIG. 13A is an enlarged sectional view illustrating a portion ‘A’ of FIG. 12, according to some example embodiments.

Referring to FIGS. 12 and 13A, each of the landing pad structures LPS may include a barrier pattern BP and a landing pad LP on the barrier pattern BP. The landing pad structures LPS may include a metal interconnection line ML and a contact C.

A level of a bottom surface LPS_L of each of the landing pad structures LPS may be lower than a level of a top surface 122U of the first upper insulating pattern 122. In some example embodiments, the landing pads LP may be or include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but example embodiments are not limited thereto. In some example embodiments, the barrier patterns BP may include at least one of metal nitride materials (e.g., titanium nitride (TiN) and tantalum nitride (TaN)), but example embodiments are not limited thereto.

Referring to FIG. 13A in conjunction with FIG. 3, the elements of FIG. 13A may correspond to respective elements of FIG. 3. In some example embodiments, each of the landing pad structures LPS may correspond to the metal line M. The contact 10 may correspond to the contact C, the metal interconnection line ML may correspond to the interconnection line 16, each of the landing pads LP may correspond to the conductive pattern 12 and the conductive interconnection line 18, and each of the barrier patterns BP may correspond to the barrier pattern 11 and the barrier interconnection line 17. The first lower insulating pattern 121 may correspond to the first insulating layer 31, and the first upper insulating pattern 122 may correspond to the second insulating layer 32. The gate insulating pattern Gox may correspond to the third insulating layer 33, and the capping pattern 220 may correspond to the fourth insulating layer 34.

Referring to FIG. 13A, in some example embodiments, the capping pattern 220 may include silicon nitride. The barrier pattern BP may be disposed on a top surface of the gate insulating pattern Gox, but may be absent on a top surface of the capping pattern 220.

FIG. 13B is an enlarged sectional view illustrating the portion ‘A’ of FIG. 12, according to some example embodiments.

Referring to FIG. 13B in conjunction with FIG. 3A, the elements of FIG. 13B may correspond to respective elements of FIG. 3A. The capping pattern 220 of FIG. 13B may correspond to the fifth insulating layer 35 of FIG. 3A.

Referring to FIG. 13B, in some example embodiments, the capping pattern 220 may include silicon oxide and/or metal oxide. The barrier pattern BP may be disposed on the top surface of the gate insulating pattern Gox and may extend on a region on the top surface of the capping pattern 220.

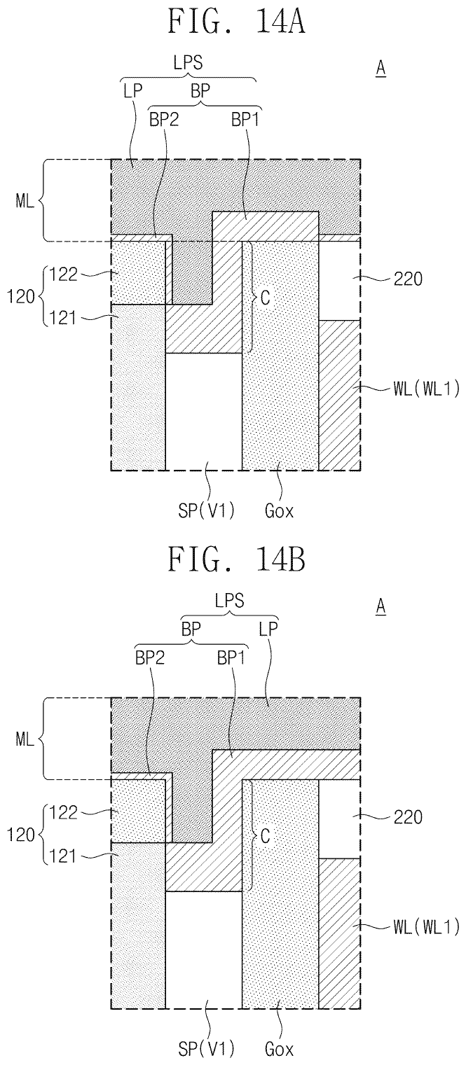

FIG. 14A is an enlarged sectional view illustrating the portion ‘A’ of FIG. 12, according to some example embodiments.

Referring to FIG. 14A in conjunction with FIG. 4B, the elements of FIG. 14A may correspond to respective elements of FIG. 4B. A first portion BP1 of the barrier pattern BP of FIG. 14A may correspond to the first portion 11A of the barrier pattern 11 and the first portion 17A of the barrier interconnection line 17 of FIG. 4B. A second portion BP2 of the barrier pattern BP of FIG. 14A may correspond to the second portion 11B of the barrier pattern 11 and the second portion 17B of the barrier interconnection line 17 of FIG. 4B. The capping pattern 220 may correspond to the fourth insulating layer 34 of FIG. 4B.

FIG. 14B is an enlarged sectional view illustrating the portion ‘A’ of FIG. 12, according to some example embodiments.

Referring to FIG. 14B in conjunction with FIG. 4B, the elements of FIG. 14B may correspond to respective elements of FIG. 4B. The capping pattern 220 of FIG. 14B may correspond to the fifth insulating layer 35 of FIG. 4B.

In a semiconductor device according to some example embodiments of the inventive concepts, a plurality of insulating layers including different insulating materials may be used to adjust a thickness of a barrier pattern.

The barrier pattern may be used to facilitate connection in a metal line deposition and to prevent, minimize or limit conductivity in a lateral direction. The barrier pattern may be formed of a material having an electric resistance higher than that of a metal line.

In the semiconductor device, according to some example embodiments of the inventive concepts, a plurality of insulating layers, which include different insulating materials, and an inhibitor, which may be deposited on only on one of the insulating layers, may be used to reduce a thickness of the barrier pattern. It may be possible to reduce an overall electric resistance of a structure including the barrier pattern and the metal line and to improve the performance of the semiconductor device.

While several example embodiments have been provided in the present disclosure, it should be understood that the disclosed systems, devices, and methods be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A semiconductor device, comprising:
a semiconductor pattern extending in a first direction;
a multi-layered insulating structure on the semiconductor pattern; and
a contact penetrating the multi-layered insulating structure, wherein
the multi-layered insulating structure comprises a first insulating layer and a second insulating layer on the first insulating layer,
the contact comprises a barrier pattern and a conductive pattern on the barrier pattern,
the barrier pattern contacts the first insulating layer and the semiconductor pattern,
the conductive pattern is spaced apart from the semiconductor pattern with the barrier pattern therebetween and the conductive pattern contacts the second insulating layer, and
the first and second insulating layers comprise different insulating materials.

2. The semiconductor device of claim 1, wherein the semiconductor pattern comprises at least one of indium-gallium-zinc oxide (IGZO), indium-tin oxide ITO, and silicon (Si).

3. The semiconductor device of claim 1, wherein the barrier pattern comprises at least one of titanium nitride (TiN) or tantalum nitride (TaN), and
the conductive pattern comprises a material different from the barrier pattern and has a higher electric conductivity than the barrier pattern.

4. The semiconductor device of claim 1, wherein the first insulating layer comprises at least one of silicon oxide or aluminum oxide, and
the second insulating layer comprises silicon nitride.

5. The semiconductor device of claim 1, wherein a height of the barrier pattern in the first direction ranges from 1.5 nm to 30 nm.

6. The semiconductor device of claim 1, wherein the multi-layered insulating structure comprises a trench exposing the semiconductor pattern, and
a width of the trench ranges from 1 nm to 20 nm in a second direction perpendicular to the first direction.

7. The semiconductor device of claim 1, further comprising an interconnection line on the contact, wherein
the first insulating layer is adjacent to the barrier pattern in a second direction perpendicular to the first direction, and
the second insulating layer is adjacent to the interconnection line in the first direction and is adjacent to the conductive pattern in the second direction.

8. The semiconductor device of claim 1, wherein the semiconductor pattern comprises a first side surface and a second side surface opposite to the first side surface,
the multi-layered insulating structure comprises a third insulating layer,
the first insulating layer contacts the first side surface of the semiconductor pattern,
the third insulating layer contacts the second side surface of the semiconductor pattern, and
the barrier pattern contacts the third insulating layer.

9. The semiconductor device of claim 8, wherein the third insulating layer comprises at least one of silicon oxide or aluminum oxide.

10. The semiconductor device of claim 8, wherein a level of a top surface of the third insulating layer is equal to or higher than a level of a top surface of the first insulating layer.

11. A semiconductor device, comprising:
a semiconductor pattern extending in a first direction;
a multi-layered insulating structure on the semiconductor pattern; and
a contact penetrating the multi-layered insulating structure, wherein
the multi-layered insulating structure comprises a first insulating layer and a second insulating layer on the first insulating layer,
the contact comprises a barrier pattern and a conductive pattern on the barrier pattern,
the barrier pattern comprises a first portion contacting the semiconductor pattern and the first insulating layer and a second portion contacting the second insulating layer,
the conductive pattern is spaced apart from the semiconductor pattern and the barrier pattern therebetween,
in the barrier pattern, a width of the second portion in a second direction perpendicular to the first direction is smaller than a width of the first portion in the second direction, and
the first and second insulating layers comprise different insulating materials.

12. The semiconductor device of claim 11, wherein, in the barrier pattern, the width of the second portion in the second direction is between 0.0001% and 3% of the width of the first portion in the second direction.

13. The semiconductor device of claim 11, wherein the semiconductor pattern comprises a first side surface and a second side surface opposite to the first side surface,
the multi-layered insulating structure comprises a third insulating layer,
the first insulating layer contacts the first side surface of the semiconductor pattern,
the third insulating layer contacts the second side surface of the semiconductor pattern, and
the first portion of the barrier pattern contacts the third insulating layer.

14. The semiconductor device of claim 13, further comprising an interconnection line on the contact,
wherein the interconnection line comprises a barrier interconnection line and a conductive interconnection line on the barrier interconnection line,
the barrier interconnection line comprises a first portion contacting the third insulating layer and a second portion contacting the second insulating layer, and
in the barrier interconnection line, a height of the second portion in the first direction is between 0.0001% and 3% of that of the first portion.

15. A semiconductor device, comprising:
a bit line extending in a first direction;
a semiconductor pattern on the bit line, the semiconductor pattern comprising a horizontal portion extending in the first direction and a vertical portion extending in a second direction perpendicular to a top surface of the bit line;
a word line on the horizontal portion and adjacent to the vertical portion in the first direction;
a gate insulating pattern between the vertical portion and the word line;
a landing pad on the vertical portion and spaced apart from the bit line with the vertical portion therebetween;
a first insulating layer on the bit line and adjacent to the vertical portion in the first direction and spaced apart from the gate insulating pattern with the vertical portion therebetween;
a second insulating layer on the first insulating layer; and
a barrier pattern between the landing pad and the vertical portion, wherein
the barrier pattern contacts the vertical portion, the gate insulating pattern, and the first insulating layer,
a level of a bottom surface of the landing pad is lower than a level of a top surface of the second insulating layer,
the first insulating layer and the gate insulating pattern comprise one of oxide and nitride materials, and
the second insulating layer comprises the other of the oxide and the nitride materials.

16. The semiconductor device of claim 15, wherein the landing pad contacts the second insulating layer.

17. The semiconductor device of claim 15, wherein the barrier pattern comprises a first portion contacting the first insulating layer and a second portion contacting the second insulating layer, and
in the barrier pattern, a width of the second portion in the first direction is less than a width of the first portion in the first direction.

18. The semiconductor device of claim 15, wherein the barrier pattern is between the landing pad and the gate insulating pattern in the first direction.

19. The semiconductor device of claim 15, wherein the semiconductor pattern comprises indium-gallium-zinc oxide (IGZO), and
the barrier pattern comprises at least one of titanium nitride (TiN) or tantalum nitride (TaN).

20. The semiconductor device of claim 15, wherein the gate insulating pattern comprises aluminum oxide,
the first insulating layer comprises silicon oxide, and
the second insulating layer comprises silicon nitride.
